(19) United States
(12) Patent Application Publication
(10) Pub. No.: US 2025/0316512 A1
(43) Pub. Date: Oct. 9, 2025

(54) METHOD FOR MONITORING GAS CONCENTRATION AND AIR PRESSURE DATA OF N2-STOCKER FOR STORING 12-INCH SEMICONDUCTOR WAFER

(71) Applicant: Shanghai Glorysoft Co., Ltd, Shanghai (CN)

(72) Inventor: Chao GAO, Shanghai (CN)

(73) Assignee: Shanghai Glorysoft Co., Ltd, Shanghai (CN)

(21) Appl. No.: 18/862,950

(22) PCT Filed: Apr. 27, 2023
(86) PCT No.: PCT/CN2023/091118

§ 371 Date: Nov. 5, 2024

(30) Foreign Application Priority Data
Oct. 16, 2022 (CN) 202211263699.1

(51) Int. Cl. H01L 21/673

(52) U.S. Cl. CPC H01L 21/67393

(57) ABSTRACT

A method for monitoring gas concentration and air pressure data of a N2-stocker (N2STK) for storing 12-inch semiconductor wafer is provided, and the method comprises: placing a wafer in the N2STK, and inquiring MES about a nitrogen charging time and a longest nitrogen supplementing interval time of the wafer by MCS; replying with the nitrogen charging time by the MES, and starting nitrogen charging after the wafer is warehoused; starting nitrogen charging time counting by the MCS, during the period thereof, if there is an ex-warehouse or warehouse-transfer requirement of the wafer, refusing to execute same by the MCS, and forbidding ex-warehouse or warehouse transfer; if the wafer is stored in the N2STK for a long time, issuing a nitrogen charging instruction again by the MCS to perform a nitrogen charging operation on the wafer; and performing an ex-warehouse operation on the wafer after nitrogen charging is completed.

### TECHNICAL FIELD

The present invention relates to the field of semiconductor process technology, and in particular to a method for monitoring a nitrogen charging time and a nitrogen supplementing execution time after a 12-inch wafer is stored in an N2-stocker (N2STK).

### RELATED ART

In the existing 12-inch wafer production system, wafers transferred from the current process to the next process need to be stored in the N2STK. The air pressure/concentration of the wafer products in the N2STK is monitored by the fault detection and classification (FDC) system (big data analysis system) and the time for nitrogen charging/supplementing of the wafer is controlled. MES combines the data collected by the FDC system to determine whether the wafer may be stored in the N2STK. Since the wafer scheduling is actually implemented by manufacturing control system (MCS), if MCS directly collects the air pressure/concentration inside the N2STK, whether the current air pressure/concentration inside the N2STK meets the wafer storage standards can be more timely and accurately determined. Also, compared with the mode in which MES only manages the N2STK shelf area, MCS manages the specific shelf locations in the N2STK, and can more accurately locate the shelves whose air pressure/concentration does not meet the wafer storage standards, thus implementing system management of manufacturing execution system (MES). At the same time, MCS is responsible for wafer scheduling, which can timely transfer and store wafers in corresponding shelf locations to avoid wafers being scrapped due to storage environment problems, and MCS being responsible for wafer scheduling is implemented. At the same time, MCS can also assign the task of inflation and pressurization to the N2STK to promptly improve the impacts of environmental issues.

The entire wafer quality monitoring and response process spans four systems: N2STK<->FDC<->MES<->MCS, as shown in FIG. 2, from the discovery of abnormal air pressure/concentration on a shelf in N2STK, wafer products are warehoused to the start of nitrogen charging in N2STK, and forbidding ex-warehouse or warehouse-transfer during nitrogen charging is controlled, an alarm is sent upon forced ex-warehouse during the period, and regular nitrogen supplementing operation is performed after long-term storage, it is necessary to make respective technical judgments in the four systems and execute corresponding processing logic to maintain the transfer scheduling of wafers and the improvement of the storage area environment, as well as to execute corresponding processing logic to maintain the quality of wafer products. The process is relatively cumbersome and the efficiency is relatively low.

### SUMMARY OF INVENTION

In order to simplify the cumbersome process across four systems, the present invention provides a method for monitoring gas concentration and air pressure data of semiconductor 12-inch N2STK.

The present invention is implemented by the following technical solutions:
a method for monitoring gas concentration and air pressure data of a semiconductor 12-inch N2STK,
the MCS system conducts comprehensive monitoring based on the nitrogen charging time required by the wafer product, and automatically supplements nitrogen when a wafer S is stored for more than a set time, which specifically comprises following steps:

(1) placing a front opening unified pod (FOUP) wafer in the N2STK, and inquiring a MES (Manufacturing Execution System) about a nitrogen charging time and a longest nitrogen supplementing interval time of the wafer by the MCS (Manufacturing Control System);

(2) by the MES, replying with the nitrogen charging time, and starting nitrogen charging after the wafer is warehoused;

(3) starting nitrogen charging time counting by the MCS, during the period thereof, if there is an ex-warehouse or warehouse-transfer requirement of the wafer, refusing to execute same by the MCS, and at this time, reporting an abnormality by the N2STK (wafer storage system) to remind a user that the wafer is being charged with nitrogen and forbidding ex-warehouse or warehouse transfer;

(4) if the wafer is stored in the N2STK for a long time, and the longest nitrogen supplementing interval time has been triggered after the nitrogen charging is completed, issuing a nitrogen charging instruction again by the MCS, so as to perform a nitrogen charging operation on the wafer;

(5) after nitrogen charging is completed, performing an ex-warehouse operation on the wafer, so as to proceed to the next process.

Furthermore, in step (2), after the MES replies to the MCS with relevant parameters, the MCS takes full control of the nitrogen charging/supplementing and control of ex-warehouse or warehouse-transfer of the FOUP wafer, and after the wafer product is warehoused, the MCS starts to perform nitrogen charging on the wafer, and the nitrogen charging time is obtained from the MES through inquiry.

Furthermore, in step (3), if the user or a system has the ex-warehouse or warehouse- transfer requirement of the wafer, but the wafer is still in the nitrogen charging process, MCS refuses to execute this ex-warehouse or warehouse-transfer task, and N2STK sends an alarm at the same time to remind the user that the wafer is being charged with nitrogen, and any ex-warehouse or warehouse transfer operation is forbidden.

Furthermore, the excessive duration for the long time stored mentioned in Step (4) is obtained from MES through inquiry.

Furthermore, after Step (5), the MCS releases control of the wafer and allows ex-warehouse of the wafer, thereby ensuring to the greatest extent possible that the wafer product meets the air pressure requirement and the gas concentration requirement of the next process.

Beneficial effect: The MCS system is responsible for collecting data on the air pressure/concentration of the N2STK. When the air pressure/concentration of a storage shelf in a certain area of N2STK is abnormal, the abnormality is reported to MES, and MES determines whether the wafer can be stored in the N2STK. Meanwhile, MCS can accurately locate the specific shelf position with the abnormal air pressure/concentration, and also assign the task of inflation and pressurization to the N2STK to promptly improve the environmental issues in the wafer storage area and improve the product yield. From data collection->wafer scheduling->inflation increase, the entire process only spans three systems (N2STK<->MCS<->MES), which streamlines the number of systems connected to the process and improves the processing efficiency of the process.

### BRIEF DESCRIPTION OF DRAWINGS

FIG. 1 is a flow chart of monitoring air pressure/concentration and controlling related nitrogen charging and nitrogen supplementing of a FOUP wafer product in a period from being warehoused to ex-warehouse in an embodiment of the present invention.

FIG. 2 is a process description of traditional gas concentration/air pressure monitoring service in the N2STK with FDC intervention involving four systems (N2STK<->FDC<->MES<->MCS).

FIG. 3 is a process description of the gas concentration/air pressure monitoring service in the N2STK of the present invention (N2STK<->MCS<->MES, without FDC intervention).

FIG. 4 content description: S2F23 TrackingData Collection (MCS->wafer product air pressure/concentration collection in the N2STK).

FIG. 5 content description: S6F1 TrackingData Collection Reply (N2STK->MCS wafer product air pressure/concentration data report).

FIG. 6 content description: S5F1 AlarmReport Send (N2STK->MCS during the nitrogen charging/supplementing period of the wafer product, after MCS refused the manual ex-warehouse task, N2STK reported the abnormality).

FIG. 7 content description: S2F25 TrackingData Fix (MCS->N2STK nitrogen charging/supplementing operation is performed on the wafer product).

### DESCRIPTION OF EMBODIMENTS

The following is a detailed description of embodiments of the present invention together with the accompanying drawings: the embodiments are implemented on the premise of the technical solution of the present invention, and a detailed implementation method and a specific operation process are given, but the protection scope of the present invention is not limited to the following embodiments.

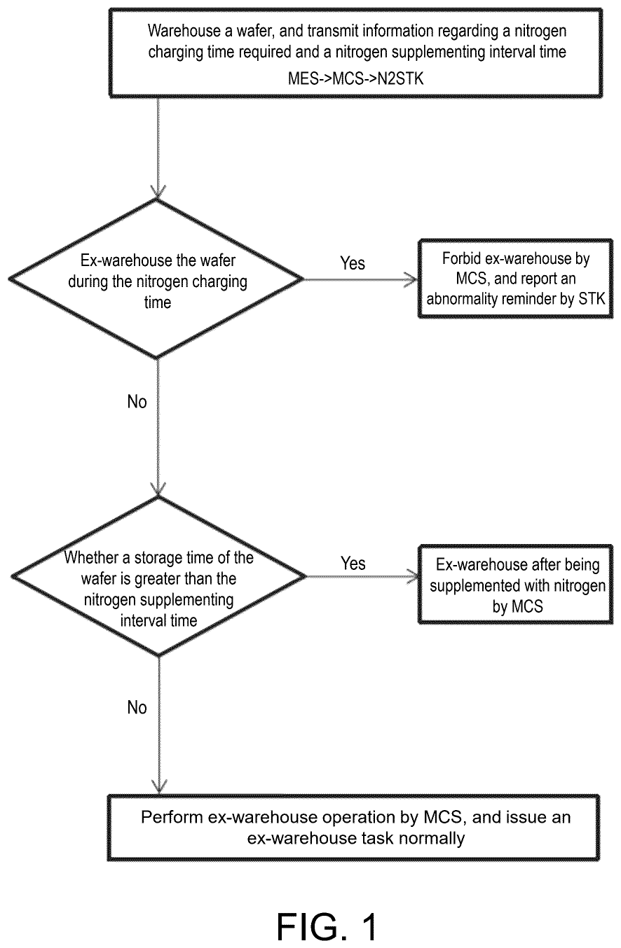

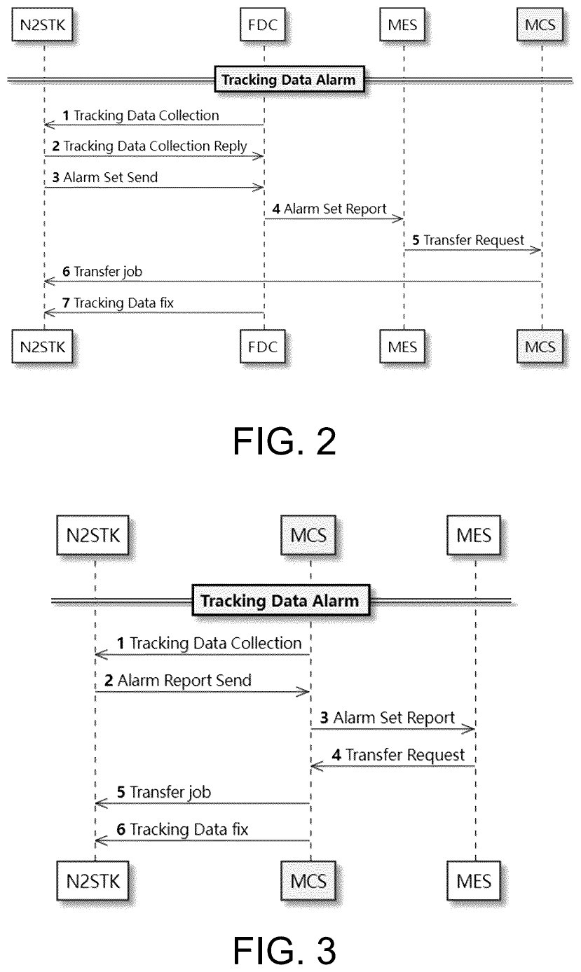

As shown in FIG. 1 and FIG. 2, when a wafers is warehoused, MCS controls a nitrogen charging time/nitrogen supplementing interval time assigned by MES. If there is a ex-warehouse or warehouse-transfer requirement during the nitrogen charging/nitrogen supplementing time, MCS refuses to issue the ex-warehouse task.

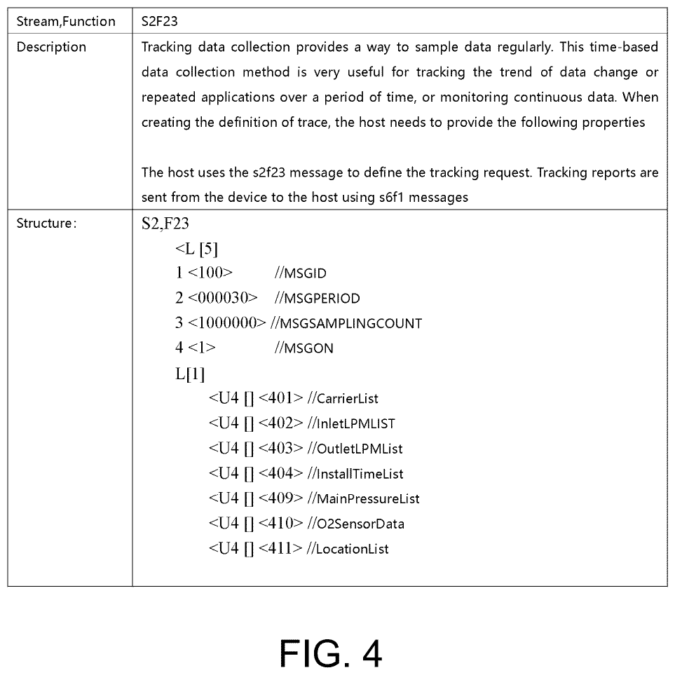

As shown in FIG. 3 and FIG. 4, if the wafer has a ex-warehouse task during the nitrogen charging/supplementing process, while MCS is in control, if the user tries to manually force the wafer to perform ex-warehouse from the N2STK, MCS is also in control and the N2STK sends an alarm, and until the nitrogen charging/supplementing is completed, the wafer is allowed for ex-warehouse. MCS regularly collects parameters such as nitrogen concentration/pressure of the wafer product in the N2STK, and automatically performs nitrogen charging/nitrogen supplementing operations based on the time assigned by MES.

A method is for monitoring gas concentration and air pressure data of an N2STK in a semiconductor 12-inch factory to determine whether the wafer stored in the STK have reached the nitrogen charging time or whether nitrogen needs to be supplemented to ensure the yield. Since the N2STK where the wafers are stored is centrally managed by the MCS, through the nitrogen charging process inside the N2STK being directly monitored by the MCS, whether the nitrogen charging of the wafer stored in the N2STK is completed, or whether nitrogen supplementing is needed after being stored for a period of time can be determined more timely and accurately. Also, during the nitrogen charging or nitrogen supplementing period, MCS forbids any operation on the wafer, including ex-warehouse or warehouse-transfer, to ensure the nitrogen charging time of the wafer and avoid wafer scrapping due to insufficient nitrogen charging, and the product yield is ensured to the greatest extent possible. Compared with the current traditional FDC control wafer nitrogen charging method, N2STK further needs to be connected with FDC, while the logistics scheduling and control of wafers are both within the scope of MCS. N2STK originally needs to interface with MCS, this invention not only improves the efficiency of nitrogen charging for wafer products, but also simplifies the system integration process (eliminating the need for FDC intervention) and improves the stability of system communication. Since each process has extremely strict standards for the gas concentration and air pressure data contained in the wafer products, if the relevant data does not meet the standards and the next process is carried out hastily, it could lead to the wafer product being scrapped. Therefore, nitrogen charging or nitrogen supplementing as required plays an important role in the semiconductor 12-inch factory, and the product yield is ensured to the greatest extent possible.

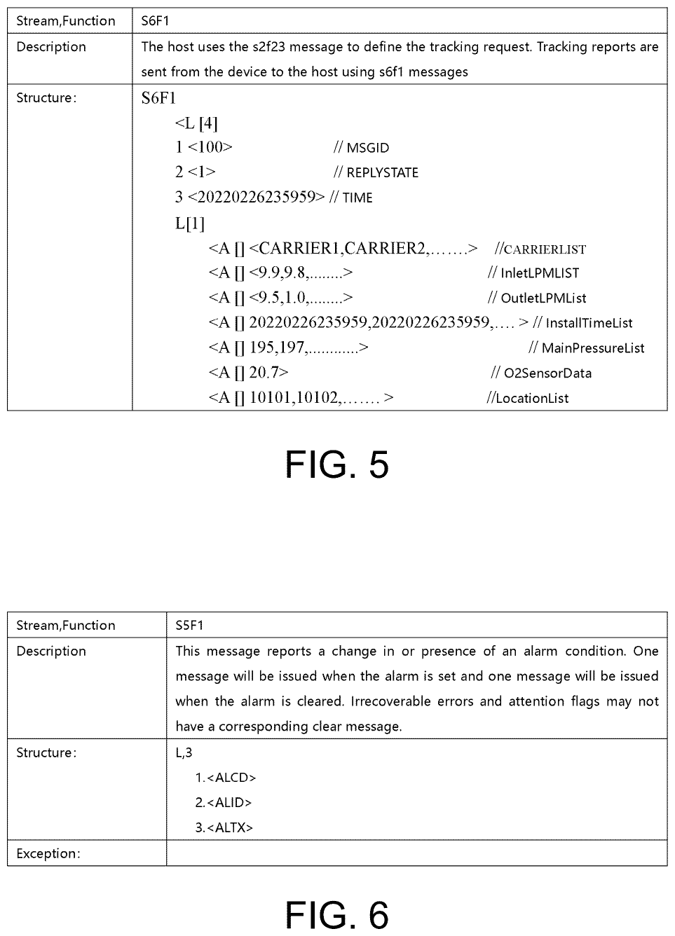

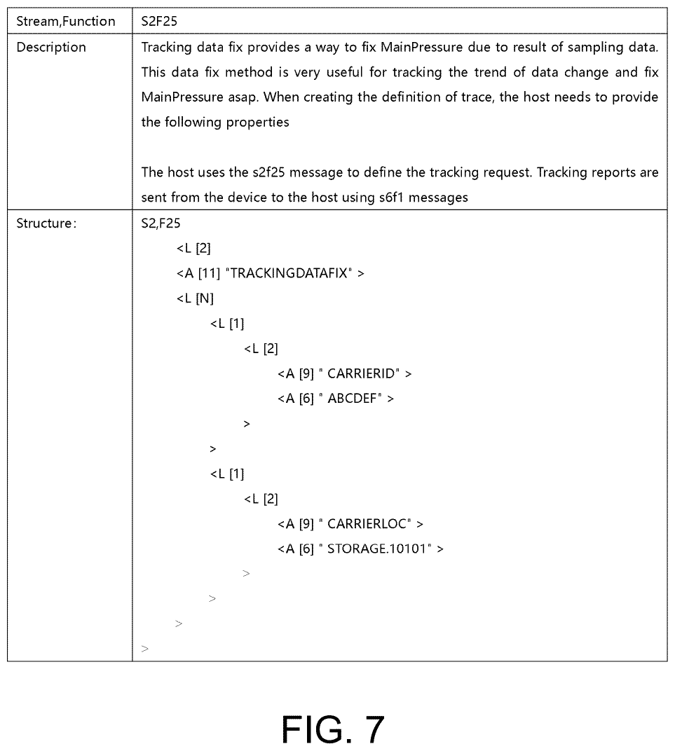

As shown in FIG. 5, FIG. 6, and FIG. 7, N2STK reports parameters such as nitrogen concentration/pressure of wafer products in the MCS warehouse so that users can monitor the quality of wafer products on the MES system. When the user manually forces an ex-warehouse task during the nitrogen charging/supplementing period, N2STK sends an alarm after MCS refuses to execute same. MCS automatically performs charging/supplementing the wafer products with nitrogen according to the nitrogen charging/supplementing time assigned by MES when the wafers are warehoused.

In order to simplify the cumbersome process across four systems (without FDC intervention), the MCS system is responsible for the data monitoring of N2STK air pressure/concentration, when the FOUP wafer is warehoused, MCS inquires MES about the nitrogen charging/supplementing time of the wafer, after MES replies to MCS with relevant parameters, MCS takes full control of the nitrogen charging/supplementing and control of ex-warehouse/warehouse-transfer of the FOUP wafer. After the wafer product is warehoused, MCS starts to charge the wafer with nitrogen (the time is obtained from MES through inquiry), during the period thereof, if the user or system has a wafer ex-warehouse or warehouse-transfer requirement, but the wafer is still in the nitrogen charging process, MCS refuses to execute the ex-warehouse/warehouse-transfer task, and N2STK sends an alarm at the same time to remind the user that the wafer is being charged with nitrogen and any ex-warehouse/warehouse-transfer operation is forbidden. After the nitrogen charging is completed, if the wafer is placed in N2STK for a long time exceeding the set time, and the excessive duration for the long-term storage is obtained through MES inquiry, MCS automatically performs nitrogen supplementing operation on the wafer product. After the nitrogen charging/nitrogen supplementing of the wafer is completed, MES issues an ex-warehouse task, so as to proceed to the next process. MCS releases control of the wafer and allows to ex-warehouse, thereby ensuring to the greatest extent that the wafer product meets the air pressure/gas concentration requirements of the next process and improving product yield.

The basic principles and main features of the present invention and the advantages of the

present invention are shown and described above. Persons skilled in the art should understand that the present invention is not limited to the above embodiments, and the above embodiments and descriptions are only for explaining the principles of the present invention, without departing from the spirit and scope of the present invention, the present invention may be subject to various changes and modifications, all of the changes and modifications fall within the scope of the present invention as claimed. The protection scope of the present invention is defined by the following claims and the equivalents thereof.

1. A method for monitoring gas concentration and air pressure data of a N2-stocker (N2STK) for storing 12-inch semiconductor wafer, characterized in that a manufacturing control system (MCS) performs comprehensive monitoring according to a nitrogen charging time required by a wafer product, and automatically supplements nitrogen when an wafer is stored for more than a set time, which specifically comprises following steps:
(1) placing a front opening unified pod (FOUP) wafer in the N2STK, and inquiring a manufacturing execution system (MES) about a nitrogen charging time and a longest nitrogen supplementing interval time of the wafer by the MCS;
(2) replying with the nitrogen charging time by the MES, and starting nitrogen charging after the wafer is warehoused;
(3) starting nitrogen charging time counting by the MCS, during a period thereof, if there is an ex-warehouse or warehouse-transfer requirement of the wafer, refusing to execute same by the MCS, and at this time, reporting an abnormality by the N2STK, which is a wafer storage system, to remind a user that the wafer is being charged with nitrogen, and forbidding ex-warehouse or warehouse transfer;
(4) issuing a nitrogen charging instruction again by the MCS if the wafer is stored in the N2STK for a long time and the longest nitrogen supplementing interval time has been triggered after the nitrogen charging is completed, so as to perform a nitrogen charging operation on the wafer;
(5) performing an ex-warehouse operation on the wafer after nitrogen charging is completed, so as to proceed to a next process.

2. The method for monitoring gas concentration and air pressure data of the N2STK for storing 12-inch semiconductor wafer according to claim 1, wherein in the step (2), after replying to the MCS with relevant parameters by the MES, the MCS takes full control of nitrogen charging/supplementing and control of ex-warehouse/warehouse-transfer of the FOUP wafer, and after the wafer product is warehoused, the MCS starts to perform nitrogen charging on the wafer, and the nitrogen charging time is obtained from the MES through inquiry.

3. The method for monitoring gas concentration and air pressure data of the N2STK for storing 12-inch semiconductor wafer according to claim 1, wherein in the step (3), if the user or a system has the ex-warehouse or warehouse-transfer requirement of the wafer, but the wafer is still in a nitrogen charging process, the MCS refuses to execute an ex-warehouse or warehouse-transfer task, and the N2STK sends an alarm to remind the user that the wafer is being charged with nitrogen and any ex-warehouse or warehouse-transfer operation is forbidden.

4. The method for monitoring gas concentration and air pressure data of the N2STK for storing 12-inch semiconductor wafer according to claim 1, wherein an excessive duration for the long time stored mentioned in the step (4) is obtained from the MES through inquiry.

5. The method for monitoring gas concentration and air pressure data of the N2STK for storing 12-inch semiconductor wafer according to claim 1, wherein after the step (5), the MCS releases control of the wafer and allows to ex-warehouse, thereby ensuring to a greatest extent that the wafer product meets an air pressure requirement and a gas concentration requirement of the next process.
